(19) United States
(12) Patent Application Publication
(10) Pub. No.: US 2017/0069615 A1
(43) Pub. Date: Mar. 9, 2017

(54) SEMICONDUCTOR DEVICE

(71) Applicant: SAMSUNG ELECTRONICS CO., LTD., SUWON-SI (KR)

(72) Inventors: HYUN-CHUL SAGONG, HWASEONG-SI (KR); SANG-WOO PAE, SEONGNAM-SI (KR); SEUNG-JIN CHOO, SUWON-SI (KR); WOO-KYUM LEE, YONGIN-SI (KR)

(21) Appl. No.: 15/239,216

(22) Filed: Aug. 17, 2016

(30) Foreign Application Priority Data
Sep. 8, 2015 (KR) 10-2015-0126843

(51) Int. Cl. H01L 27/02; H01L 27/08; H01L 29/739; H01L 29/165; H01L 29/06

(52) U.S. Cl. CPC H01L 27/0248; H01L 29/165; H01L 29/0638; H01L 29/7391; H01L 27/0814

(57) ABSTRACT

There is provided a semiconductor device capable of suppressing generation of leakage current of a diode, by applying a voltage to a gate of a gated junction diode (GJD). The semiconductor device includes an internal circuit connected with an input-output terminal, and an electrostatic discharge (ESD) protection circuit configured to protect the internal circuit from ESD, the ESD protection circuit including a first diode, wherein the first diode includes a first gate which is formed on a substrate and to which a first recovery voltage is applied, a first well of a first conductivity type which is formed within the substrate and under the first gate, a first impurity region of the first conductivity type which is formed on one side of the first gate and within the first well and is higher in doping concentration than that of the first well, and a second impurity region of a second conductivity type which is formed on other side of the first gate and within the first well.

### CROSS-REFERENCE TO RELATED APPLICATION

This application claims priority under 35 U.S.C. 119 to Korean Patent Application No. 10-2015-0126843, filed on Sep. 8, 2015, in the Korean Intellectual Property Office, the contents of which are incorporated by reference herein in their entirety.

### TECHNICAL FIELD

The present disclosure generally relates to a semiconductor device, and more particularly, to a semiconductor device including a diode.

### DISCUSSION OF RELATED ART

The integrated circuit (IC) of complementary metal oxide semiconductor (CMOS) is quite susceptible to the influence of high voltage or high current caused by static electricity, such as static electricity generated when the IC is in contact with human body, etc. In such instance, an inflow of high voltage or high current to an IC chip can damage the insulating film or result in channel disconnection, which in turn can disable the internal operation of the IC.

To prevent this shortcoming, an electrostatic discharge (ESD) protection circuit installed at the IC's input and output circuits, discharges the static electricity in advance and thus prevents high voltage or high current from flowing into internal elements of the IC.

### SUMMARY

A semiconductor device capable of suppressing generation of leakage current of a diode, by applying a voltage to a gate of a gated junction diode (GJD) is provided.

According to an aspect of the present inventive concept, there is provided a semiconductor device including: an internal circuit connected with an input-output terminal; and an electrostatic discharge (ESD) protection circuit configured to protect the internal circuit from ESD, the ESD protection circuit including a first diode. The first diode includes: a first gate is formed on a substrate and to which a first recovery voltage is applied; a first well of a first conductivity type is formed within the substrate and under the first gate; a first impurity region of the first conductivity type is formed on one side of the first gate and within the first well, in which the first impurity region is higher in doping concentration than that of the first well; and a second impurity region of a second conductivity type is formed on other side of the first gate and within the first well.

The second impurity region is connected with the input-output terminal, and the first gate is not electrically connected with the first impurity region and the second impurity region.

The first well is an n-type well, and the first recovery voltage is a positive (+) voltage.

The first well is a p-type well, and the first recovery voltage is a negative (−) voltage.

The ESD protection circuit further includes a second diode. The second diode includes: a second gate which is formed on the substrate; a second well of the second conductivity type, which is formed within the substrate and under the second gate; a third impurity region of the second conductivity type, which is formed on one side of the second gate and within the second well, is higher in doping concentration than that of the second well; and a fourth impurity region of the first conductivity type, which is formed on other side of the second gate and within the second well.

A second recovery voltage is applied to the second gate, and the fourth impurity region is connected with the input-output terminal.

The second gate is not electrically connected with the third impurity region and the fourth impurity region.

The first recovery voltage and the second recovery voltage are different from each other.

The semiconductor device may further contain a transistor which includes a third gate, and a source/drain of the second conductivity type. The source/drain is formed on both sides of the third gate. The first recovery voltage is applied to the third gate.

The semiconductor device may further include a buried channel layer formed within the substrate. An energy bandgap of the buried channel layer is smaller than that of the substrate.

According to another aspect of the present inventive concept, there is provided a semiconductor device including: a first well of a first conductivity type and a second well of a second conductivity type, which are formed within a substrate; a first impurity region of the first conductivity type, which is formed within the first well and connected to a first terminal voltage; a second impurity region of a second conductivity type, which is formed within the first well; a third impurity region of the second conductivity type, which is formed within the second well and connected to a second terminal voltage which is different from the first terminal voltage; a fourth impurity region of the first conductivity type, which is formed within the second well and electrically connected with the second impurity region; a first gate formed on the substrate between the first impurity region and the second impurity region; and a second gate formed on the substrate between the third impurity region and the fourth impurity region, in which a first recovery voltage applied to the first gate and a second recovery voltage applied to the second gate have different signs from each other.

The first well is an n-type well, and the first recovery voltage is a positive (+) voltage.

The first well is a p-type well, and the first recovery voltage is a negative (−) voltage.

A doping concentration of the first impurity region and a doping concentration of the second impurity region are higher than a doping concentration of the first well, and a doping concentration of the third impurity region and a doping concentration of the fourth impurity region are higher than a doping concentration of the second well.

The first gate is not electrically connected with the first impurity region and the second impurity region, and the second gate is not electrically connected with the third impurity region and the fourth impurity region.

The semiconductor device may further contain a transistor including a third gate, and a source/drain of the second conductivity type. The source/drain is formed on both sides of the third gate, in which the first recovery voltage is applied to the third gate.

The semiconductor device may further include a buried channel layer formed within the substrate, in which an energy bandgap of the buried channel layer is smaller than that of the substrate.

The substrate is a silicon substrate, and the buried channel layer is a silicon germanium layer.

According to yet another aspect of the present inventive concept, there is provided a semiconductor device including: an internal circuit connected with an input-output terminal; and an electrostatic discharge (ESD) protection circuit configured to protect the internal circuit from ESD, the ESD protection circuit including a first diode and a second diode. The first diode includes: a first gate formed on a substrate and to which a first recovery voltage is applied, a first well of a first conductive type formed under the first gate within the substrate, and a first impurity region of the first conductivity type and a second impurity region of a second conductive type formed within the first well on each side of the first gate. The second diode includes: a second gate formed on the substrate and to which a second recovery voltage is applied, a second well of the second conductive type formed under the second gate within the substrate, and a third impurity region of the second conductivity type and a fourth impurity region of the first conductive type formed within the second well on each side of the second gate. The second impurity region and the fourth impurity region are electrically connected to the input-output terminal.

The first well is an n-type well, and the first recovery voltage is a positive (+) voltage.

### BRIEF DESCRIPTION OF THE DRAWINGS

The above and other features of the present disclosure will become more apparent to those of ordinary skill in the art when the detailed exemplary embodiments are read with reference to the accompanying drawings, in which:

FIG. 1 is a circuit diagram provided to explain a semiconductor device according to an exemplary embodiment of the present disclosure;

FIG. 2 is a layout diagram provided to explain a semiconductor device according to an exemplary embodiment of the present disclosure;

FIG. 3 is a cross-sectional view taken on line A-A of FIG. 2 according to an exemplary embodiment of the present disclosure;

FIG. 4 is a cross-sectional view taken on line B-B of FIG. 2 according to an exemplary embodiment of the present disclosure;

FIGS. 5A to 6C are views provided to explain an effect of a semiconductor device according to an exemplary embodiment of the present disclosure;

FIG. 7 is a view provided to explain a semiconductor device, in which the second well extends to under the first well according to an exemplary embodiment of the present disclosure;

FIG. 8 is a view provided to explain a semiconductor device, in which the first well and the second well are separated by the field insulating film according to an exemplary embodiment of the present disclosure;

FIG. 9 is a view provided to explain a semiconductor device, in which the first gate insulating film is formed between the substrate and the first gate, and between the first gate and the first spacer according to an exemplary embodiment of the present disclosure;

FIG. 10 is a view provided to explain a semiconductor device including buried channel layers according to an exemplary embodiment of the present disclosure;

FIG. 11 is a view provided to explain a bandgap structure under a gate of FIG. 10 according to an exemplary embodiment of the present disclosure;

FIG. 12 is a view provided to explain a semiconductor device, in which the impurity regions include semiconductor patterns according to an exemplary embodiment of the present disclosure;

FIGS. 13 and 14 are views provided to explain a semiconductor device including a fin-type pattern according to an exemplary embodiment of the present disclosure;

FIG. 15 is a view provided to explain a semiconductor device, in which the first buried channel layer is positioned higher than the upper surface of the field insulating film according to an exemplary embodiment of the present disclosure;

FIG. 16 is a view provided to explain a semiconductor device including a first buried channel layer and a capping pattern according to an exemplary embodiment of the present disclosure;

FIG. 17 is a circuit diagram provided to explain a semiconductor device according to an exemplary embodiment of the present disclosure;

FIG. 18 is a cross sectional view of an area I of FIG. 17 according to an exemplary embodiment of the present disclosure;

FIG. 19 is a block diagram of a SoC system comprising a semiconductor device according to an exemplary embodiment of the present disclosure;

FIG. 20 is a block diagram of an electronic system comprising a semiconductor device according to an exemplary embodiment of the present disclosure; and

FIGS. 21 to 23 illustrate exemplary semiconductor systems which may apply therein semiconductor devices according to an exemplary embodiment of the present disclosure.

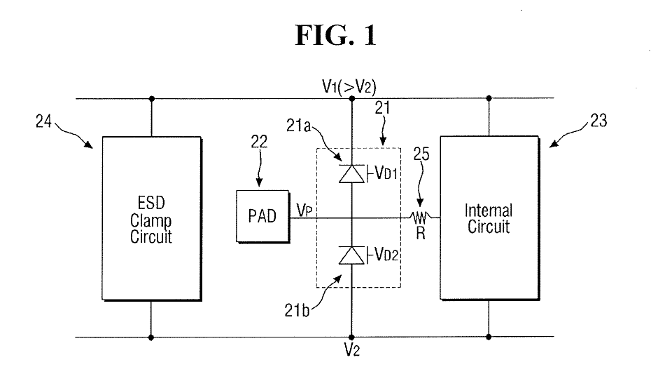

Since the drawings in FIGS. 1-23 are intended for illustrative purpose, the elements in the drawings are not necessarily drawn to scale. For example, some of the elements may be enlarged or exaggerated for clarity purpose.

### DETAILED DESCRIPTION OF THE EMBODIMENTS

Features of the present inventive concept and methods of accomplishing the same may be understood more readily by reference to the following detailed description of preferred exemplary embodiments and the accompanying drawings. The present inventive concept may, however, be embodied in many different forms and should not be construed as being limited to the specific exemplary embodiments set forth herein. Rather, these exemplary embodiments are provided so that this disclosure will be thorough and complete and will fully convey the concept of the present disclosure to those skilled in the art.

It will be understood that when an element or layer is referred to as being “connected to” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout the specification. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms “first”, “second”, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept.

The use of the terms “a”, “an”, “the” and similar referents in the context of describing the invention (especially in the context of the following claims) are to be construed to cover both the singular and the plural, unless otherwise indicated herein or clearly contradicted by context. The terms “comprising”, “having”, “including” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illustrate the invention and is not a limitation on the scope of the invention unless otherwise specified. Further, unless defined otherwise, all terms defined in the generally used dictionaries may not be overly interpreted.

Hereinbelow, a semiconductor device according to an exemplary embodiment of the present disclosure will be explained with reference to FIGS. 1 to 6C.

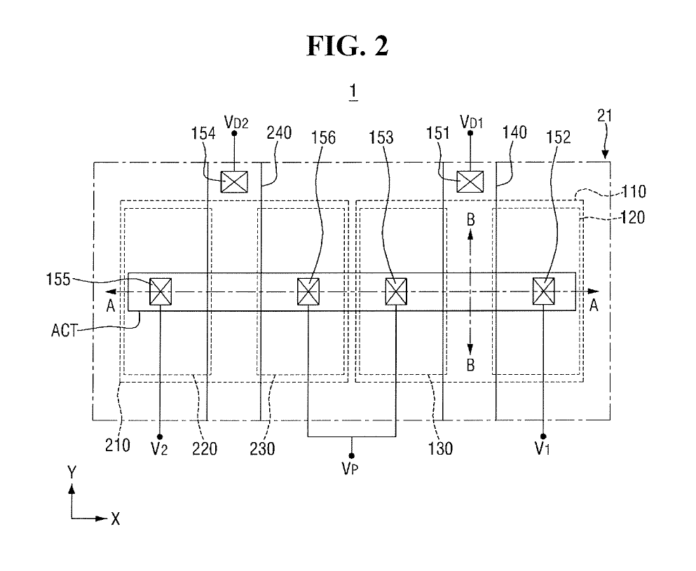

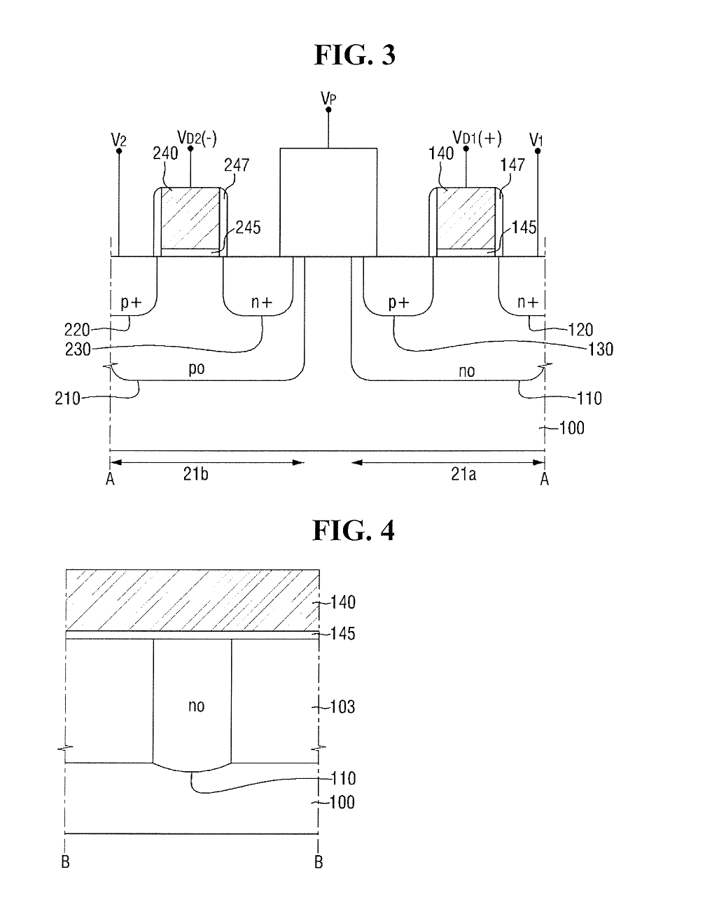

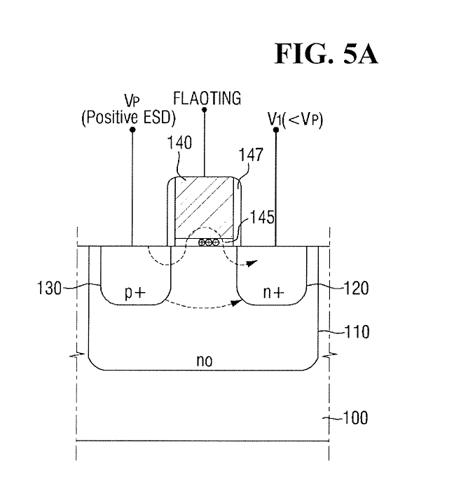

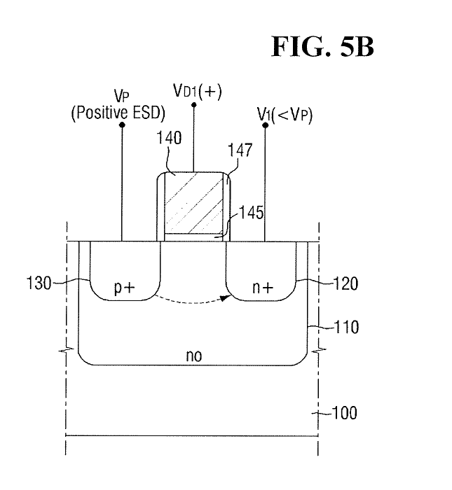

FIG. 1 is a circuit diagram provided to explain a semiconductor device according to an exemplary embodiment of the present disclosure. FIG. 2 is a layout diagram provided to explain a semiconductor device according to an exemplary embodiment of the present disclosure. FIG. 3 is a cross-sectional view taken on line A-A of FIG. 2. FIG. 4 is a cross-sectional view taken on line B-B of FIG. 2. FIGS. 5A to 6C are views provided to explain an effect of a semiconductor device according to an exemplary embodiment of the present disclosure.

For reference, FIG. 2 is a layout diagram representing the ESD protection element of FIG. 1. FIGS. 2 and 3 represent terminal voltage of the circuit diagram shown in FIG. 1. For convenience of explanation, FIG. 3 skips illustration of the contacts 151-156 of FIG. 2.

While the circuit diagram of FIG. 1 represents a certain exemplary embodiment of the present disclosure applicable as an ESD protection element, the present disclosure is not limited thereto. Accordingly, a diode included in a semiconductor device according to an exemplary embodiment of the present disclosure may be applied to not only an ESD protection element, but also a semiconductor device where a diode is applicable. Moreover, the semiconductor device may apply therein not only the two serially-connected diodes as illustrated in FIG. 1, but also one single diode. In addition, two or more diodes may be serially-connected, in parallel, or the combination thereof for the semiconductor device in FIG. 1.

Referring to FIG. 1, a semiconductor device according to an exemplary embodiment of the present disclosure may include an ESD protection element 21.

The ESD protection element 21 may include a first diode 21a and a second diode 21b connected in series with each other. The first diode 21a and the second diode 21b may be, for example, gated junction diodes (GJDs). The GJD may be a semiconductor device that combines the function of a p-n junction and a metal oxide semiconductor (MOS) capacitor.

One end of the ESD protection element 21 may be connected to a first terminal voltage V1, while the other end is connected to a second terminal voltage V2. Further, the first diode 21a and the second diode 21b may be connected with an input-output terminal 22. That is, an input-output terminal voltage Vp of the input-output terminal 22 may be connected to the ESD protection element 21 between the first diode 21a and the second diode 21b. That is, one end of the first diode 21a may be connected to a first terminal voltage V1, and the other end of the second diode 21b may be connected to an input-output terminal voltage Vp. Further, one end of the second diode 21b may be connected to a second terminal voltage V2, and the other end of the second diode 21b may be connected to the input-output terminal voltage Vp.

When the semiconductor device is not in ESD shock state, the first terminal voltage V1 may be larger than the second terminal voltage V2 to prevent the electric current from flowing into the first diode 21a and the second diode 21b.

The first diode 21a included in the ESD protection element 21 may be a p-type diode, and the second diode 21b may be an n-type diode. The “p-type diode” as used herein refers to a diode in which holes flow, thus allowing the current to flow, and the “n-type diode” refers to a diode in which electrons flow, thus allowing the current to flow. In other words, if a positive voltage is applied to the p-type diode, or a negative voltage is applied to the n-type diode, current can flow. On the contrary, if a negative voltage is applied to the p-type diode and a positive voltage to the n-type diode, no current flows.

A first gate 140 (FIG. 2) of the first diode 21a may be connected to a first recovery voltage V_{D1}. A second gate 240 (FIG. 2) of the second diode 21b may be connected to a second recovery voltage V_{D2}. For example, the first recovery voltage V_{D1} may be applied to the first gate of the first diode 21a, and the second recovery voltage V_{D2} may be applied to the second gate of the second diode 21b. The first recovery voltage V_{D1} and the second recovery voltage V_{D2} may be different voltages from each other. Further, the signs of the first recovery voltage V_{D1} and the second recovery voltage V_{D2} may be opposite to each other. For example, when the first recovery voltage V_{D1} is a positive voltage, the second recovery voltage V_{D2} may be a negative voltage. Alternatively, the first recovery voltage V_{D1} may be a negative voltage, in which case the second recovery voltage V_{D2} may be a positive voltage. Choices of voltages and signs described above for the first recovery voltage V_{D1} and the second recovery voltage V_{D2} may depend on the structures of the first diode 21a and the second diode 21b.

The first recovery voltage V_{D1} and the second recovery voltage V_{D2} will be described below, with reference to an example in which the first diode 21a is a p-type diode and the second diode 21b is an n-type diode.

As illustrated in FIG. 5B, when the first diode 21a, which is the p-type diode, includes an n-type well, the first recovery voltage V_{D1} applied to the first gate of the first diode 21a may be the positive voltage. Further, as illustrated in FIG. 6B, when the second diode 21b, which is the n-type diode, includes a p-type well, the second recovery voltage V_{D2} applied to the second gate of the second diode 21b may be the negative voltage.

As an alternative to a configuration as shown in FIG. 5B, when the first diode 21a, which is the n-type diode, includes a p-type well, the first recovery voltage V_{D1} applied to the first gate of the first diode 21a may be the negative voltage. Further, as alternative to a configuration as shown in FIG. 6B, when the second diode 21b, which is the p-type diode, includes an n-type well, the second recovery voltage V_{D2} applied to the second gate of the second diode 21b may be the positive voltage. Thus, the signs of the recovery voltages applied to the gates of the diodes may vary depending on whether the diodes are p-types or n-types, and may also be determined according to types of the impurity wells (e.g., n-type well, p-type well) included in the diodes.

For convenience of explanation, the first diode 21a is described hereinafter as a p-type diode with an n-type well as illustrated in FIG. 5B, and the second diode 21b as the n-type diode includes a p-type well as illustrated in FIG. 6B.

Referring to FIG. 1, an internal circuit 23 may be connected with the input-output terminal 22. A resistor R 25 may be disposed between the internal circuit 23 and the input-output terminal 22. The internal circuit 23 may include a variety of circuits to perform functions of a semiconductor device.

The internal circuit 23 may be protected from the ESD by the ESD protection element 21. That is, when ESD occurs, the ESD protection element 21 may protect the internal circuit 23 from the ESD.

An ESD clamping circuit 24 may be connected with the ESD protection element 21.

Referring to FIGS. 2 to 4, the semiconductor device 1 according to an exemplary embodiment of the present disclosure may include the first diode 21a and the second diode 21b.

The semiconductor device 1 according to an exemplary embodiment of the present disclosure may be formed in an active region ACT which is defined by a field insulating film 103.

The field insulating film 103 may be formed within the substrate 100. For example, the field insulating film 103 may be an oxide film, a nitride film, an oxynitride film or a film combining these.

The active region ACT defined by the field insulating film 103 may extend laterally in a first direction X.

A substrate 100 may include a base substrate, and an epitaxial layer grown on the base substrate, but not limited thereto. The substrate 100 may include the base substrate only, i.e., it may not include the epitaxial layer. The substrate 100 may be a silicon substrate, a gallium arsenide substrate, a silicon germanium substrate, a ceramic substrate, a quartz substrate, a glass substrate for display, or a semiconductor on insulator (SOI) substrate.

Hereinbelow, a silicon substrate will be described as an example. Further, the substrate 100 may be, for example, a first conductivity type (e.g., p-type).

The first diode 21a may include a first gate 140, a first well 110, a first impurity region 120, and a second impurity region 130.

The first gate 140 may extend in a second direction Y. The first gate 140 may be formed so as to intersect the active region ACT, and may be formed on the substrate 100.

The first gate 140 may include at least one of polycrystalline silicon (poly Si), amorphous silicon (a-Si), titanium (Ti), titanium nitride (TiN), tungsten nitride (WN), titanium aluminum (TiAl), titanium aluminum nitride (TiAlN), tantalum nitride (TaN), titanium carbide (TiC), tantalum carbide (TaC), tantalum carbonitride (TaCN), tantalum silicon nitride (TaSiN), tantalum (Ta), cobalt (Co), ruthenium (Ru), aluminum (Al) and tungsten (W).

When the first gate 140 includes silicon, the first gate 140 may include silicide material.

Referring to FIG. 2, a first contact 151 may be formed on the first gate 140, and may be electrically connected with the first gate 140.

The first recovery voltage V_{D1} may be applied to the first gate 140 via the first contact 151, and may be applied with a positive voltage.

A first spacer 147 may be formed on a sidewall of the first gate 140. For example, the first spacer 147 may include at least one of silicon nitride (SiN), silicon oxynitride (SiON), silicon oxide (SiO₂), silicon oxycarbonitride (SiOCN), and a combination thereof.

A first gate insulating film 145 may be formed between the substrate 100 and the first gate 140. As illustrated, the first gate insulating film 145 may extend on the upper surface of the field insulating film 103, but this is provided only for convenience of explanation and the present disclosure is not limited thereto.

The first gate insulating film 145 that was disposed between the first spacer 147 and the first gate 140 and formed along the sidewall of the first spacer 147 may be omitted.

The first gate insulating film 145 may include silicon oxide, silicon oxynitride, silicon nitride and a high-k dielectric material with a higher dielectric constant than silicon oxide. For example, the high-k dielectric material may include one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but not limited thereto.

The first well 110 may be formed within the substrate 100, and may be formed under the first gate 140.

When the first diode 21a is a p-type diode, the first well 110 may be an n-type well.

The first impurity region 120 may be formed on one side of the first gate 140, and may be formed within the first well 110. That is, the first well 110 may be formed under the first impurity region 120 to surround the first impurity region 120.

The first impurity region 120 may be the same n-type impurity region as the first well 110, and may have a doping concentration which is relatively higher than that of the first well 110.

A second impurity region 130 may be formed on the other side of the first gate 140, and may be formed within the first well 110.

The first gate 140 may be formed on the substrate 100 between the first impurity region 120 and the second impurity region 130. That is, the first gate 140 may be formed on the first well 110 between the first impurity region 120 and the second impurity region 130.

The first well 110 may be formed under the second impurity region 130 to surround the second impurity region 130.

The second impurity region 130 may be a p-type impurity region, unlike the first well 110 or the first impurity region 120. The second impurity region 130 may have a doping concentration which is relatively higher than that of the first well 110.

Referring to FIG. 2, a second contact 152 may be formed on the first impurity region 120, and may be electrically connected to the first impurity region 120.

A third contact 153 may be formed on the second impurity region 130, and may be electrically connected to the second impurity region 130.

The first impurity region 120 may be connected to the first terminal voltage V1 via the second contact 152. The second impurity region 130 may be connected to the input-output terminal voltage Vp of the input-output terminal 22 via the third contact 153.

In a semiconductor device according to an exemplary embodiment of the present disclosure, the first gate 140 may not be electrically connected to the first impurity region 120 and the second impurity region 130.

The second diode 21b may include a second gate 240, a second well 210, a third impurity region 220, and a fourth impurity region 230.

The second gate 240 may extend in the second direction Y, and may be formed so as to intersect the active region ACT. The first gate 140 may be formed on the substrate 100, and the second gate 240 may be disposed abreast with the first gate 140.

A fourth contact 154 may be formed on the second gate 240, and may be electrically connected to the second gate 240.

The second recovery voltage V_{D2} may be applied to the second gate 240 via the fourth contact 154, and may be applied with a negative voltage.

A second spacer 247 may be formed on a sidewall of the second gate 240.

A second gate insulating film 245 may be formed between the substrate 100 and the second gate 240. The second gate insulating film 245 may not be formed between the second spacer 247 and the second gate 240, and may not be formed along the sidewall of the second spacer 247.

The second well 210 may be formed within the substrate 100. The second well 210 may be formed under the second gate 240, and may be formed in the substrate 100 and in isolation from the first well 110.

When the second diode 21b is an n-type diode, the second well 210 may be a p-type well.

The third impurity region 220 may be formed on one side of the second gate 240, and may be formed within the second well 210. That is, the second well 210 may be formed under the third impurity region 220 to surround the third impurity region 220.

The third impurity region 220 may be the same p-type impurity region as the second well 210, and may have a doping concentration which is relatively higher than that of the second well 210.

The fourth impurity region 230 may be formed on the other side of the second gate 240, and may be formed within the second well 210.

The second gate 240 may be formed on the substrate 100 between the third impurity region 220 and the fourth impurity region 230. For example, the second gate 240 may be formed on the second well 210 between the third impurity region 220 and the fourth impurity region 230.

The second well 210 may be formed under the fourth impurity region 230 to surround the fourth impurity region 230.

The fourth impurity region 230 may be an n-type impurity region, unlike the second well 210 or the third impurity region 220. The fourth impurity region 230 may have a doping concentration which is relatively higher than the second well 210.

Referring to FIG. 2, a fifth contact 155 may be formed on the third impurity region 220, and may be electrically connected with the third impurity region 220.

A sixth contact 156 may be formed on the fourth impurity region 230, and may be electrically connected with the fourth impurity region 230.

The third impurity region 220 may be connected with the second terminal voltage V2 via the fifth contact 155. The fourth impurity region 230 may be connected with the input-output terminal voltage Vp of the input-output terminal 22 via the sixth contact 156. That is, the second impurity region 130 of the first diode 21a and the fourth impurity region 230 of the second diode 21b may be electrically connected, and may be connected to the input-output terminal voltage Vp.

In a semiconductor device according to an exemplary embodiment of the present disclosure, the second gate 240 may not be electrically connected with the third impurity region 220 and the fourth impurity region 230.

As illustrated in FIG. 3, the positive first recovery voltage V_{D1} may be applied to the first gate 140 of the first diode 21a, and the negative second recovery voltage V_{D2} may be applied to the second gate 240 of the second diode 21b, but this is provided only for illustrative purpose and the present disclosure is not limited thereto. In other words, the positive first recovery voltage V_{D1} may be applied to the first gate 140 of the first diode 21a, and the second gate 240 of the second diode 21b may be in floating state. On the contrary, the negative second recovery voltage V_{D2} may be applied to the second gate 240 of the second diode 21b, and the first gate 140 of the first diode 21a may be in floating state.

The effect of a semiconductor device according to an exemplary embodiment of the present disclosure will be explained with reference to FIGS. 1 and 5A to 6C.

With reference to FIGS. 1, 5A and 5B, an example in which a positive ESD is applied to the input-output terminal voltage Vp will be described. Referring to FIGS. 1 and 5C, an example in which the semiconductor device is not in the ESD shock state will be described.

FIG. 5A is a view provided to explain an example in which a semiconductor device is affected by the ESD shock while the first gate 140 of the first diode is in floating state. FIG. 5B is a view provided to explain an example in which a semiconductor device is affected by the ESD shock while the first recovery voltage V_{D1} is applied to the first gate 140 of the first diode. FIG. 5C is a view provided to explain an example after a semiconductor device is out of the ESD shock while the first recovery voltage V_{D1} is applied to the first gate 140 of the first diode.

When there is no ESD occurring, the input-output terminal voltage Vp of the input-output terminal 22 is applied to the internal circuit via the resistor 25. At this time, since the first diode 21a and the second diode 21b are in reverse-biased stress state, the first diode 21a and the second diode 21b may be both in open state.

When the positive ESD occurs at the input-output terminal 22, the input-output terminal voltage Vp becomes greater than the first terminal voltage V 1. Accordingly, current flows through the first diode 21a. That is, the first diode 21a may absorb the positive ESD occurring at the input-output terminal 22.

When the first gate 140 of the first diode 21a is in floating state, there may be two current paths (i.e., travel paths for hole) (dotted line in FIG. 5A) in the first diode 21a. That is, the first current path in the first diode 21a may be a course of moving holes from the second impurity region 130, past the first well 110, and toward the first impurity region 120. The second current path in the first diode 21a may be a course of moving holes from the second impurity region 130, past the first gate insulating film 145 and the first gate 140, and toward the first impurity region 120.

When a positive ESD occurs at the input-output terminal 22 and causes the current to flow through the first diode 21a, some of the holes moving through the second current path may be trapped in the first gate insulating film 145. After the positive ESD of the input-output terminal 22 dissipates, the holes trapped in the first gate insulating film 145 may cause leakage current.

When the positive first recovery voltage V_{D1} is applied to the first gate 140 of the first diode 21a, there may be one current path (dotted line in FIG. 5B) in the first diode 21a. More specifically, when the positive first recovery voltage V_{D1} is applied to the first gate 140, the holes in the first well 110 are distanced away from the boundary between the first gate insulating film 145 and the substrate 100. Accordingly, when the positive ESD occurs at the input-output terminal 22 and causes the current to flow through the first diode 21a, the current in the first diode 21a will flow from the second impurity region 130, past the first well 110, and toward the first impurity region 120. That is, the application of the positive first recovery voltage V_{D1} to the first gate 140 can prevent the current in the first diode 21a from flowing from the second impurity region 130, past the first gate insulating film 145 and the first gate 140, and toward the first impurity region 120. Consequently, when positive ESD occurs at the input-output terminal 22 and causes the current to flow through the first diode 21a, the holes moving in the first diode 21a may not be trapped in the first gate insulating film 145.

Referring to FIG. 5C, the application of the positive first recovery voltage V_{D1} to the first gate 140 can minimize the holes trapped in the first gate insulating film 145 in the first diode 21a.

After the positive ESD of the input-output terminal 22 dissipates, the input-output terminal voltage Vp may become smaller than the first terminal voltage V1, and the first diode 21a returns to the reverse-biased stress state. Because the hole trapping in the first gate insulating film 145 is minimized due to the application of the first recovery voltage V_{D1} to the first gate 140, the leakage current at the first diode 21a in the reverse-biased stress state can be alleviated.

With reference to FIGS. 1, 6A and 6B, an example in which negative ESD is applied to the input-output terminal voltage Vp will be described. Referring to FIGS. 1 and 6C, an example in which the semiconductor device is not in the ESD shock state will be described.

FIG. 6A is a view provided to explain an example in which a semiconductor device is affected by the ESD shock while the second gate 240 of the second diode is in floating state. FIG. 6B is a view provided to explain an example in which a semiconductor device is affected by the ESD shock while the second recovery voltage V_{D2} is applied to the second gate 240 of the second diode. FIG. 6C is a view provided to explain an example after a semiconductor device is out of the ESD shock while the second recovery voltage V_{D2} is applied to the second gate 240 of the second diode.

When the negative ESD occurs at the input-output terminal 22, the input-output terminal voltage Vp becomes smaller than the second terminal voltage V2. Accordingly, current flows through the second diode 21b. That is, the second diode 21b may absorb the negative ESD occurring at the input-output terminal 22. At this time, when the second gate 240 of the second diode 21b is in floating state, there may be two electron travel paths (dotted line in FIG. 6A) in the second diode 21b. The current paths in the second diode 21b may be opposite to the electron travel paths. That is, the first electron mobility path in the second diode 21b may be a course of moving electrons from the fourth impurity region 230, past the second well 210, and toward the third impurity region 220. The second electron mobility path in the second diode 21b may be a course of moving electrons from the fourth impurity region 230, past the second gate insulating film 245 and the second gate 240, and toward the third impurity region 220.

When the negative ESD occurs at the input-output terminal 22 and causes the current to flow through the second diode 21b, some of the electrons moving through the second electron mobility path may be trapped in the second gate insulating film 245.

After the negative ESD of the input-output terminal 22 dissipates, the electrons trapped in the second gate insulating film 245 may cause leakage current.

When the negative second recovery voltage V_{D2} is applied to the second gate 240 of the second diode 21b, there may be one electron travel path (dotted line in FIG. 6B) in the second diode 21b. In other words, when the negative second recovery voltage V_{D2} is applied to the second gate 240, the electrons in the second well 210 are distanced away from the boundary between the second gate insulating film 245 and the substrate 100. Accordingly, when the negative ESD occurs at the input-output terminal 22 and causes the current to flow through the second diode 21b, the current in the second diode 21b will flow from the third impurity region 220, past the second well 210, and toward the fourth impurity region 230. For example, the application of the negative second recovery voltage V_{D2} to the second gate 240 can prevent the current in the second diode 21b from flowing from the third impurity region 220, past the second gate insulating film 245 and the second gate 240, and toward the fourth impurity region 220.

When negative ESD occurs at the input-output terminal 22, the second diode 21b provides a path for the electrons to flow through and not be trapped in the second gate insulating film 245.

Referring to FIG. 6C, the application of the negative second recovery voltage V_{D2} to the second gate 240 can minimize the electrons trapped in the second gate insulating film 245 in the second diode 21b.

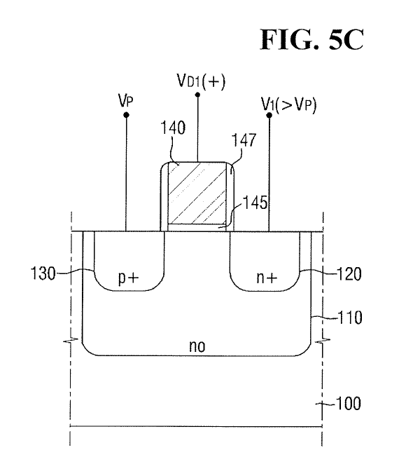

After the negative ESD of the input-output terminal 22 dissipates, the input-output terminal voltage Vp may become greater than the second terminal voltage V2, and the second diode 21b returns to the reverse-biased stress state. Because the electron trapping in the second gate insulating film 245 is minimized due to the application of the second recovery voltage V_{D2} to the second gate 240, the leakage current at the second diode 21b in the reverse-biased stress state can be alleviated. Thus, either singly or in combination, the first and second diodes 21a and 21b, with applying first and second recovery voltages V_{D1} and V_{D2} to the first and second gates 140 and 240 provide both positive and negative ESD protection to the internal circuit 23. Each of FIGS. 7-9 is a view provided to explain a semiconductor device according to an exemplary embodiment of the present disclosure. For convenience of explanation, differences that are not explained above with reference to FIGS. 1 to 6B will be mainly explained below.

For reference, FIGS. 7 to 9 skip illustration of the terminal voltage illustrated in FIG. 3.

Referring to FIG. 7, in a semiconductor device 2 according to an exemplary embodiment of the present disclosure, the second well 210 may extend to under the first well 110.

The second well 210 may be formed under the first well 110 so as to surround the first well 110. That is, the first well 110 may be formed within the second well 210.

As an alternative to the illustrated example, the first well 110 may be formed under the second well 210 so as to surround the second well 210. The first well 110 may extend to under the second well 210.

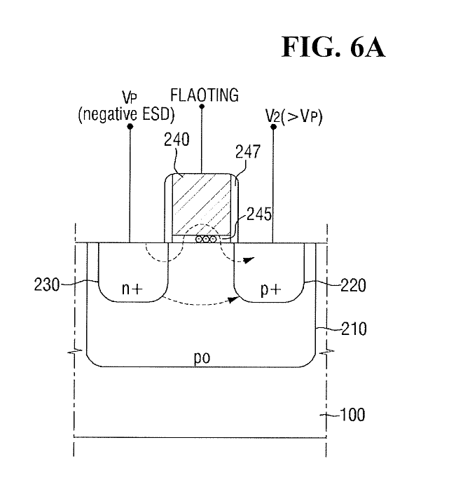

Referring to FIG. 8, in a semiconductor device 3 according to an exemplary embodiment of the present disclosure, the first well 110 and the second well 210 may be separated by the field insulating film 103.

As illustrated, the first well 110 and the second well 210 may be formed to the depths greater than the depth at which the field insulating film 103 is formed, although the present disclosure is not limited thereto.

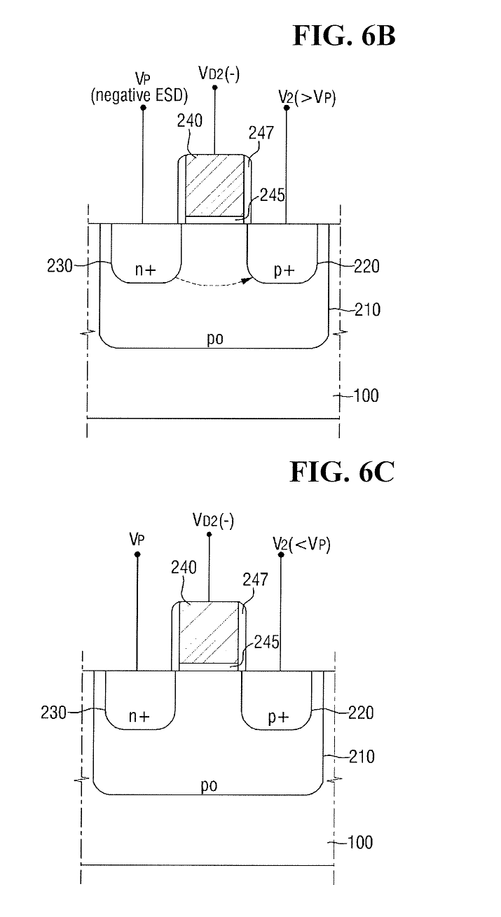

Referring to FIG. 9, in a semiconductor device 4 according to an exemplary embodiment of the present disclosure, the first gate insulating film 145 may be formed not only between the substrate 100 and the first gate 140, but also between the first gate 140 and the first spacer 147.

The first gate insulating film 145 may be formed along the upper surface of the substrate 100 and the sidewall of the first spacer 147.

Further, the second gate insulating film 245 may be formed not only between the substrate 100 and the second gate 240, but also between the second gate 240 and the second spacer 247. The second gate insulating film 245 may be formed along the upper surface of the substrate 100 and the sidewall of the second spacer 247. Additionally, the first gate 140 and the second gate 240 may be formed by, for example, replacement process (or gate last process), but not limited thereto.

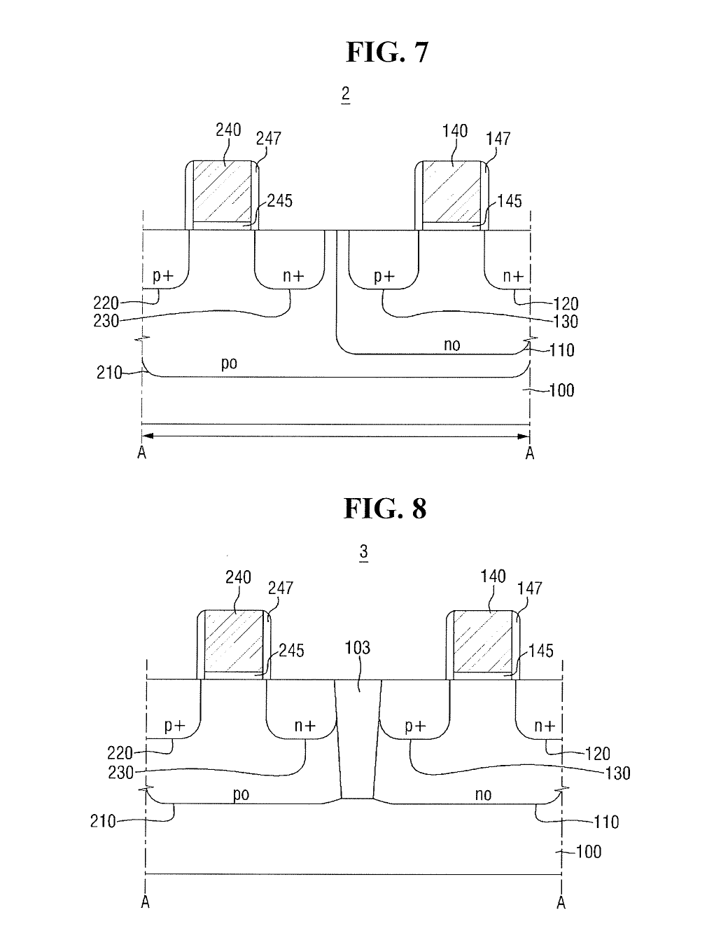

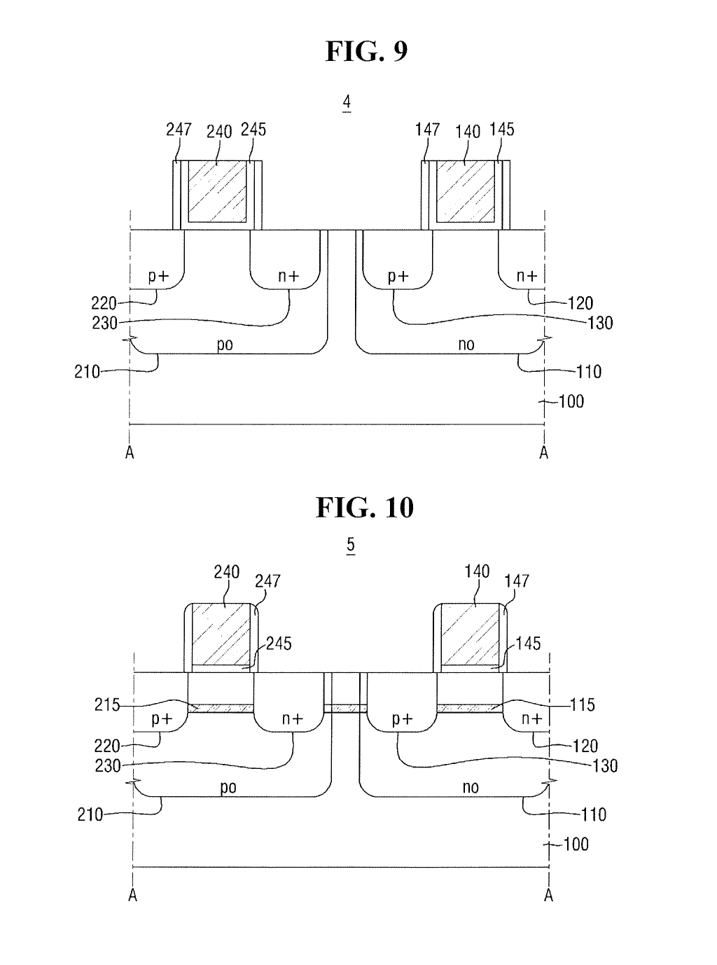

FIG. 10 is a view provided to explain a semiconductor device according to an exemplary embodiment of the present disclosure. FIG. 11 is a view provided to explain a bandgap structure under a gate of FIG. 10. For convenience of explanation, differences that are not explained above with reference to FIGS. 1 to 6C will be mainly explained below.

For reference, FIG. 10 skips illustration of the terminal voltage illustrated in FIG. 3.

Referring to FIGS. 10 and 11, the semiconductor device 5 according to an exemplary embodiment of the present disclosure may additionally include a first buried channel layer 115 and a second buried channel layer 215.

The first buried channel layer 115 and the second buried channel layer 215 may be formed within the substrate 100. The first buried channel layer 115 may be positioned under the first gate 140, and the second buried channel layer 215 may be positioned under the second gate 240.

The first buried channel layer 115 may be spaced apart from the first gate insulating film 145, and the second buried channel layer 215 may be spaced apart from the second gate insulating film 245.

The depth at which the first buried channel layer 115 is formed may be shallower than the depth at which the first well 110 is formed, and the depth at which the second buried channel layer 215 is formed may be shallower than the depth at which the second well 210 is formed.

The first buried channel layer 115 and the second buried channel layer 215 may be formed at a same level. The term “same level” as used herein refers to being formed by the same fabricating process. In other words, the first buried channel layer 115 and the second channel layer 215 may be formed at the same process step(s) during the fabrication process of the semiconductor device.

The energy bandgap of the first buried channel layer 115 and the energy bandgap of the second buried channel layer 215 may be smaller than the energy bandgap of the substrate 100. For example, when the substrate 100 is a silicon substrate, the first buried channel layer 115 and the second buried channel layer 215 may be silicon germanium layers, in which silicon germanium has smaller bandgap than silicon.

In FIG. 11, the first buried channel layer 115 and the second buried channel layer 215, which have smaller energy bandgaps than that of the substrate 100, may form a potential well in the substrate 100.

In terms of energy, the potential well is more stable than others around it. Accordingly, electrons or holes can gather toward the potential well.

When the semiconductor device is affected by the ESD shock, the holes flowing in the first diode 21a or the electrons flowing in the second diode 21b may move through the potential well which is energetically stable. That is, when the semiconductor device is affected by the ESD shock, the first buried channel layer 115 and the second buried channel layer 215 may be used as the current paths of the first diode 21a and the second diode 21b, respectively.

Electrical charges may be kept from being trapped in the first gate insulating film 145 and the second gate insulating film 245 by using the first buried channel layer 115 and the second buried channel layer 215 spaced apart from the first gate insulating film 145 and the second gate insulating film 245, as current paths. Because the hole trapping in the first gate insulating film 145 is minimized due to the existence of the first buried channel layer 115, the leakage current at the first diode 21a in the reverse-biased stress state after ESD shock can be alleviated. Similarly, because the electron trapping in the second gate insulating film 245 is minimized due to the existence of the second buried channel layer 215, the leakage current at the second diode 21b in the reverse-biased stress state after ESD shock can be alleviated.

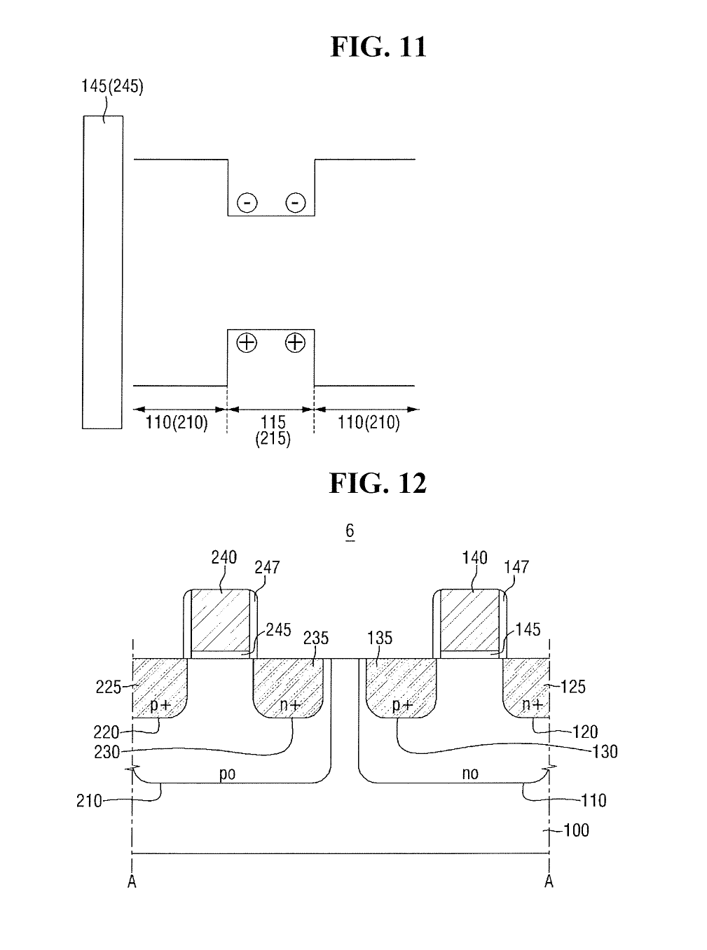

FIG. 12 is a view provided to explain a semiconductor device according to an exemplary embodiment of the present disclosure. For convenience of explanation, differences that are not explained above with reference to FIGS. 1 to 6B will be mainly explained below.

For reference, FIG. 12 skips illustration of the terminal voltage illustrated in FIG. 3.

Referring to FIG. 12, in the semiconductor device 6 according to an exemplary embodiment of the present disclosure, the first impurity region 120 may include a first semiconductor pattern 125, and the second impurity region 130 may include a second semiconductor pattern 135.

The third impurity region 220 may include a third semiconductor pattern 225, and the fourth impurity region 230 may include a fourth semiconductor pattern 235.

The first to the fourth semiconductor patterns 125, 135, 225, 235 may each include an epitaxial film.

Further, as an alternative to the illustration, the first to the fourth semiconductor patterns 125, 135, 225, 235 may include upper surfaces elevated higher than the upper surface of the substrate 100.

The first to the fourth semiconductor patterns 125, 135, 225, 235 may include the same material, but not limited thereto. That is, the first semiconductor pattern 125 and the fourth semiconductor pattern 235 (i.e., n-type) may include the same material as each other, and the second semiconductor pattern 135 and the third semiconductor pattern 225 (i.e., p-type) may include the same material as each other. In this case, the first semiconductor pattern 125 (i.e., n-type pattern) and the second semiconductor pattern 135 (i.e., p-type pattern) may include different materials from each other.

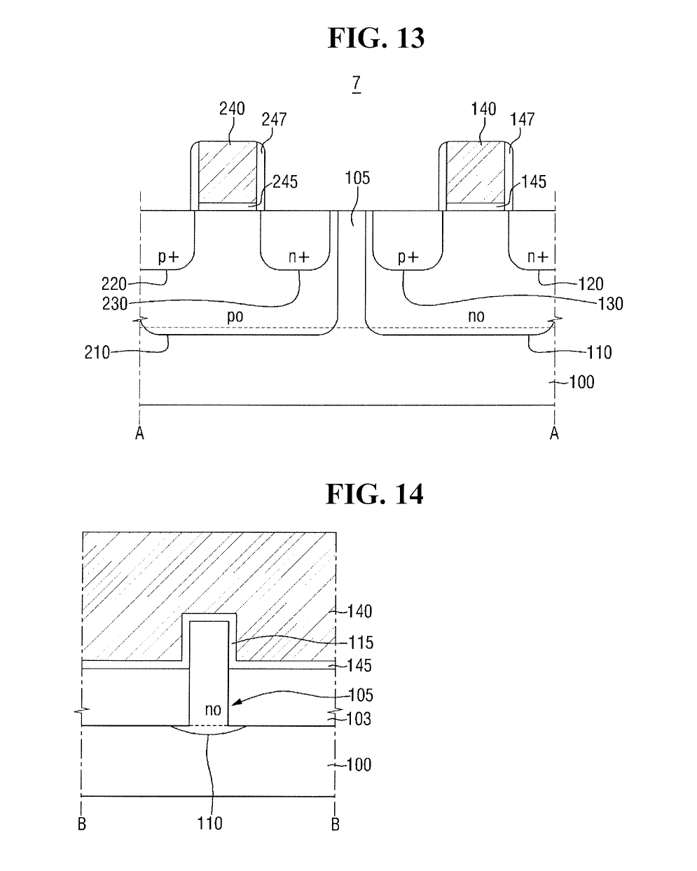

FIGS. 13 and 14 are views provided to explain a semiconductor device according to an exemplary embodiment of the present disclosure. For convenience of explanation, differences that are not explained above with reference to FIGS. 1 to 6B will be mainly explained below.

For reference, FIG. 13 is a cross-sectional view taken on line A-A of FIG. 2, and FIG. 14 is a cross sectional view taken on line B-B of FIG. 2. Further, FIG. 13 skips illustration of the terminal voltage illustrated in FIG. 3.

Referring to FIGS. 13 and 14, in the semiconductor device 7 according to an exemplary embodiment of the present disclosure, the substrate 100 may additionally include a fin-type pattern 105.

A field insulating film 103 be formed on the substrate 100, and may partially surround the sidewall of the fin-type pattern 105. The fin-type pattern 105 may include a portion that protrudes upward higher than the upper surface of the field insulating film 103.

The fin-type pattern 105 may include an element semiconductor material such as, for example, silicon or germanium. Further, the fin-type pattern 105 may include a compound semiconductor such as, for example, IV-IV group compound semiconductor or III-V group compound semiconductor.

Take the IV-IV group compound semiconductor for instance, the fin-type pattern 105 may be a binary compound or a ternary compound including at least two or more of carbon (C), silicon (Si), germanium (Ge), and tin (Sn), or may be the above-mentioned binary or ternary compound doped with IV group element.

Take III-V group compound semiconductor for instance, the fin-type pattern 105 may be a binary compound, ternary compound or quaternary compound which is formed as a III group element which may be at least one of aluminum (Al), gallium (Ga), and indium (In), or may be the above mentioned binary compound, ternary compound or quaternary compound combined with a V group element which may be one of phosphorus (P), arsenic (As) and antimony (Sb).

For convenience of explanation, it is assumed hereinbelow that the fin-type pattern 105 is a silicon fin-type pattern.

The first gate 140 and the second gate 240 may be formed so as to intersect the fin-type pattern 105 protruding higher than the upper surface of the field insulating film 103.

The first gate insulating film 145 may be formed between the fin-type pattern 105 and the first gate 140. The first gate insulating film 145 may be formed along a profile of the fin-type pattern 105 protruding upward higher than the field insulating film 103.

The first well 110 and the second well 210 may be formed within the fin-type pattern 105. The first well 110 and the second well 210 may extend past the fin-type pattern 105, to the substrate 100. That is, portions of the first well 110 and the second well 210 may be formed within the substrate 100.

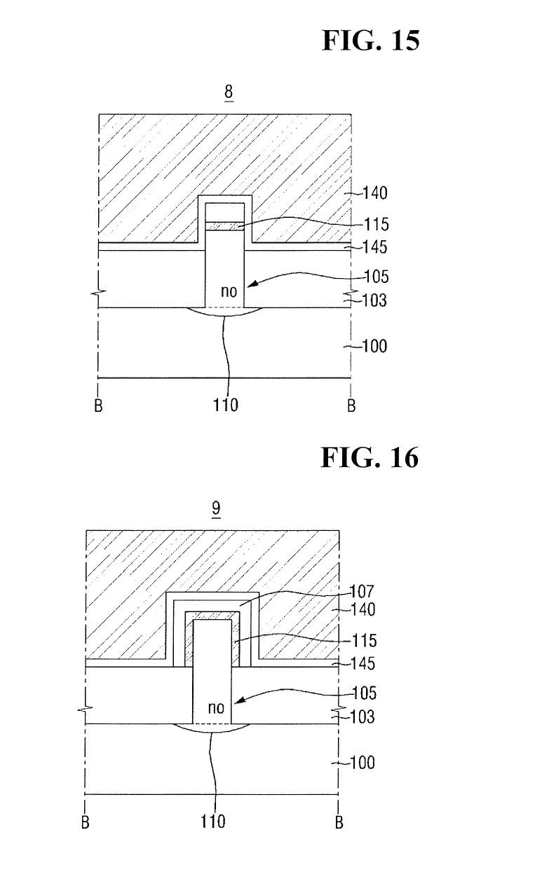

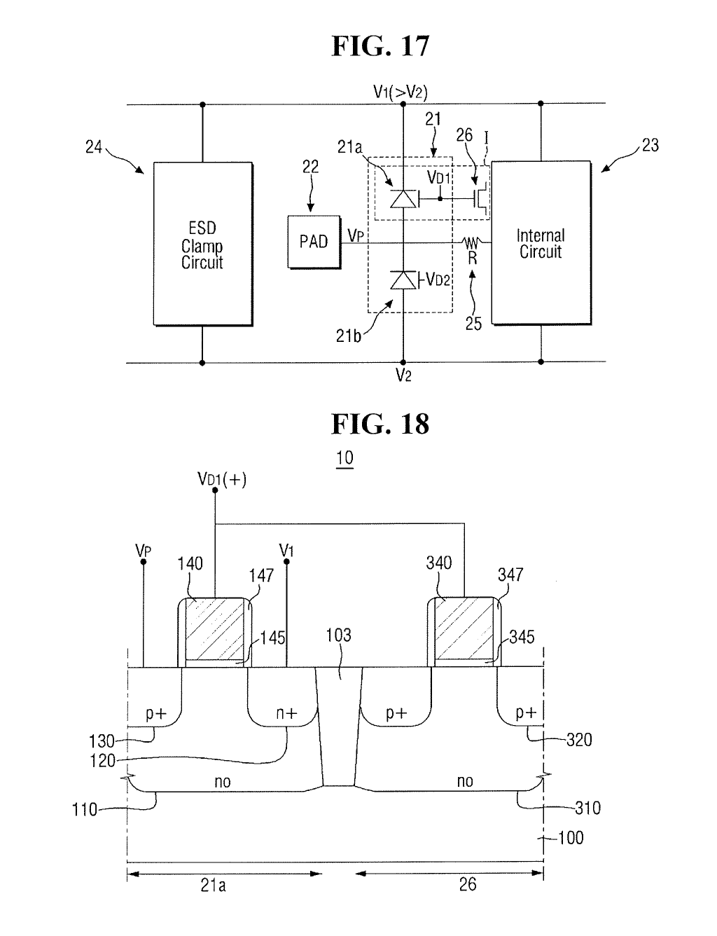

FIG. 15 is a view provided to explain a semiconductor device according to an exemplary embodiment of the present disclosure. FIG. 16 is a different view provided to explain a semiconductor device according to an exemplary embodiment of the present disclosure. For convenience of explanation, differences that are not explained above with reference to FIGS. 13 and 14 will be mainly explained below.

For reference, FIGS. 15 and 16 are cross-sectional views taken on line B-B of FIG. 3. Further, in the semiconductor device according to an exemplary embodiment of the present disclosure, the cross-sectional views taken along the fin-type pattern 105 in FIGS. 15 and 16 may be similar to FIG. 10.

Referring to FIG. 15, the semiconductor device 8 according to an exemplary embodiment of the present disclosure may additionally include the first buried channel layer 115 interposed between the fin-type patterns 105. For example, the first buried channel layer 115 may be positioned higher than the upper surface of the field insulating film 103.

The energy bandgap of the first buried channel layer 115 may be smaller than the energy bandgap of the fin-type pattern 105.

While FIG. 15 shows only the intersection with the first gate 140, of course, the same cross-sectional view in FIG. 15 is also applicable to the intersection with the second gate 240.

Referring to FIG. 16, the semiconductor device 9 according to an exemplary embodiment of the present disclosure may additionally include a first buried channel layer 115 and a capping pattern 107.

The first buried channel layer 115 may be formed along the profile of the fin-type pattern 105 protruding upward higher than the upper surface of the field insulating film 103. The first buried channel layer 115 may be formed along the profile of the fin-type pattern 105, using epitaxial growth method.

The capping pattern 107 may be formed on the first buried channel layer 115, and may be formed along the profile of the fin-type pattern 105 protruding upward higher than the upper surface of the field insulating film 103. The capping pattern 107 may be formed using the epitaxial growth method. For example, the capping pattern 107 may include silicon, and the first buried channel layer 115 may, for example, include silicon germanium.

The energy bandgap of the first buried channel layer 115 may be smaller than the energy bandgap of the fin-type pattern 105. The energy bandgap of the capping pattern 107 may be greater than the energy bandgap of the first buried channel layer 115.

The first gate insulating film 145 may be formed on the capping pattern 107, along the profile of the capping pattern 107.

While FIG. 16 shows only the intersection with the first gate 140, of course, the same cross-sectional view in FIG. 16 is also applicable to the intersection with the second gate 240.

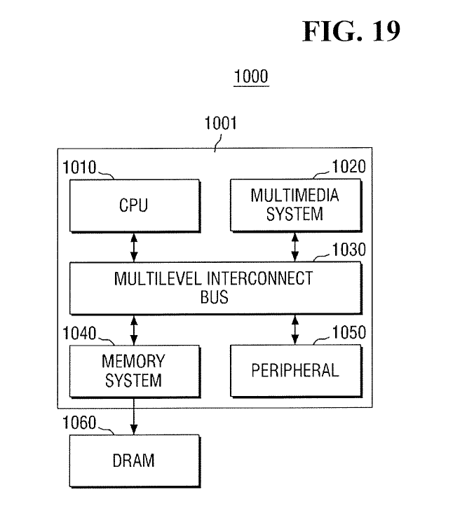

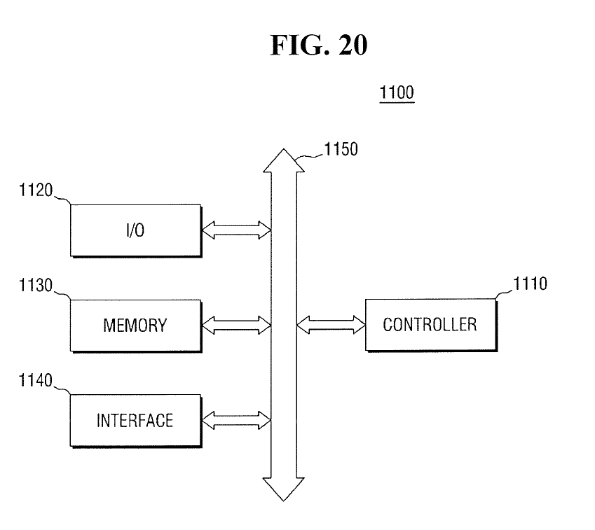

FIG. 17 is a circuit diagram provided to explain a semiconductor device according to an exemplary embodiment of the present disclosure. FIG. 18 is a cross-sectional view of an area I of FIG. 17. For convenience of explanation, differences that are not explained above with reference to FIGS. 1 to 6C will be mainly explained below.

For reference, FIG. 18 represents the terminal voltage of the circuit diagram shown in FIG. 17. Further, among the ESD protection elements 21, FIG. 18 illustrates only the first diode 21a and a transistor 26 connected to the first diode 21a.

Referring to FIGS. 17 and 18, the semiconductor device 10 according to an exemplary embodiment of the present disclosure may additionally include the transistor 26 which includes a third gate 340 electrically connected with the first gate 140 of the first diode 21a.

As illustrated, the transistor 26 may not be included in the internal circuit 23, but the present disclosure is not limited thereto. It is of course possible that the transistor 26 is part of a circuit included in the internal circuit 23.

The first diode 21a and the transistor 26 may be separated by the field insulating film 103 formed within the substrate 100, but this is the example provided only for illustrative purpose and the present disclosure is not limited thereto.

The transistor 26 may include the third gate 340, and a source/drain 320.

The third gate 340 may be formed on the substrate 100, and may be electrically connected with the first gate 140 of the first diode 21a. More specifically, the first recovery voltage V_{D1} may be applied to the third gate 340 connected with the first gate 140. For the transistor 26, the first recovery voltage V_{D1} may be an operating voltage of the third gate 340.

The third gate 340 may include at least one of polycrystalline silicon (poly Si), amorphous silicon (a-Si), titanium (Ti), titanium nitride (TiN), tungsten nitride (WN), titanium aluminum (TiAl), titanium aluminum nitride (TiAlN), tantalum nitride (TaN), titanium carbide (TiC), tantalum carbide (TaC), tantalum carbonitride (TaCN), tantalum silicon nitride (TaSiN), tantalum (Ta), cobalt (Co), ruthenium (Ru), aluminum (Al) and tungsten (W).

A third spacer 347 may be formed on a sidewall of the third gate 340. For example, the third spacer 347 may include at least one of silicon nitride (SiN), silicon oxynitride (SiON), silicon oxide (SiO₂), silicon oxycarbonitride (SiOCN), and a combination thereof.

A third gate insulating film 345 may be formed between the substrate 100 and the third gate 340. Like the first gate insulating film 145, the third gate insulating film 345 may not be formed between the third spacer 347 and the third gate 340, but not limited thereto. That is, the shape of the third gate insulating film 345 as formed may be different from the shape of the first gate insulating film 145 as formed.

The third gate insulating film 345 may include, for example, silicon oxide, silicon oxynitride, silicon nitride or a high-k dielectric material with a higher dielectric constant than silicon oxide. For example, the high-k dielectric material may include one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but not limited thereto.

The third well 310 may be formed within the substrate 100, and may be formed under the third gate 340. The third well 310 may be the same n-type well as the first well 110.

The source/drain 320 may be formed on both sides of the third gate 340, and may be formed in the third well 310. Unlike the third well 310, the source/drain 320 may be a p-type source/drain.

In FIG. 17, the semiconductor device 10 may additionally include another transistor which is connected with the second diode 21b among the ESD protection elements 21. In an exemplary embodiment of the present inventive concept, one or more additional transistors may be serially-connected, parallelly-connected, or combination thereof to the first diode 21a and the second diode 21b among the ESD protection elements 21.

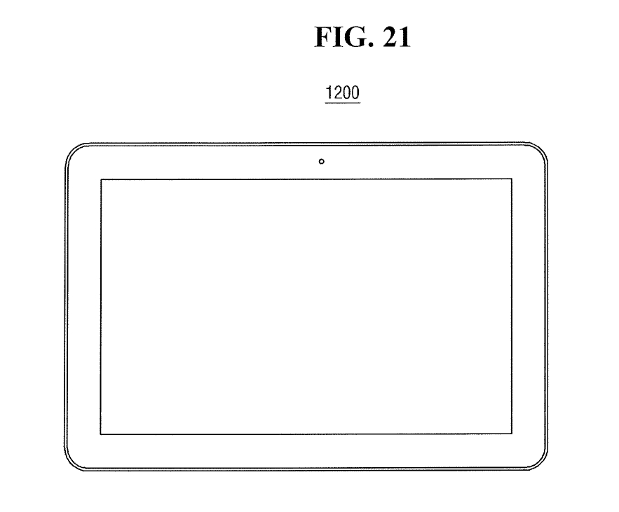

FIG. 19 is a block diagram of a SoC system comprising a semiconductor device according to an exemplary embodiment of the present disclosure.

Referring to FIG. 19, a SoC system 1000 includes an application processor 1001 and a dynamic random-access memory (DRAM) 1060.

The application processor 1001 may include a central processing unit (CPU) 1010, a multimedia system 1020, a bus 1030, a memory system 1040 and a peripheral circuit 1050.

The CPU 1010 may perform arithmetic operation necessary for driving the SoC system 1000. In an exemplary embodiment of the present disclosure, the CPU 1010 may be configured on a multi-core environment which includes a plurality of cores.

The multimedia system 1020 may be used for performing a variety of multimedia functions on the SoC system 1000, and may include a three-dimensional (3D) engine module, a video codec, a display system, a camera system, or a post-processor.

The bus 1030 may be used for exchanging data communication among the CPU 1010, the multimedia system 1020, the memory system 1040 and the peripheral circuit 1050. In an exemplary embodiment of the present disclosure, the bus 1030 may have a multi-layer structure. Specifically, an example of the bus 1030 may be a multi-layer advanced high-performance bus (AHB), or a multi-layer advanced eXtensible interface (AXI), but not limited herein.

The memory system 1040 may provide environments necessary for the application processor 1001 to connect to an external memory (e.g., DRAM 1060) and perform high-speed operation. In an exemplary embodiment of the present disclosure, the memory system 1040 may include a separate controller (e.g., DRAM controller) to control an external memory (e.g., DRAM 1060).

The peripheral circuit 1050 may provide environments necessary for the SoC system 1000 to have a seamless connection to an external device (e.g., main board). Accordingly, the peripheral circuit 1050 may include a variety of interfaces to allow compatible operation with the external device connected to the SoC system 1000.

The DRAM 1060 may function as an operation memory necessary for the operation of the application processor 1001. In an exemplary embodiment of the present disclosure, the DRAM 1060 may be arranged externally to the application processor 1001, as illustrated. Specifically, the DRAM 1060 may be packaged into a package on package (PoP) type with the application processor 1001.

At least one of the above-mentioned components of the SoC system 1000 may include at least one of the semiconductor devices according to the exemplary embodiments explained above.

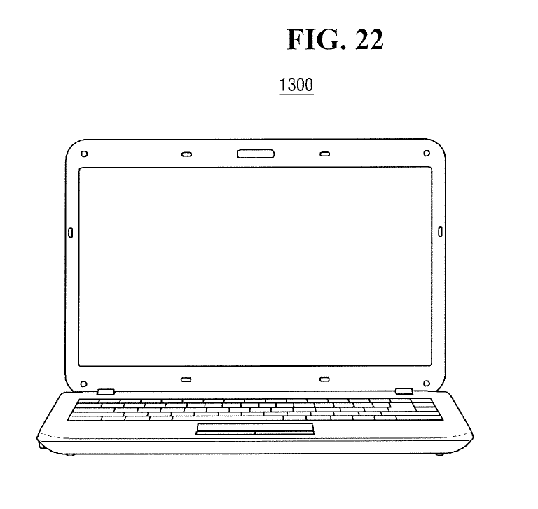

FIG. 20 is a block diagram of an electronic system comprising a semiconductor device according to an exemplary embodiment of the present disclosure.

Referring to FIG. 20, the electronic system 1100 may include a controller 1110, an input/output (I/O) device 1120, a memory device 1130, an interface 1140 and a bus 1150. The controller 1110, the I/O device 1120, the memory device 1130 and/or the interface 1140 may be coupled with one another via the bus 1150. The bus 1150 corresponds to a path through which data travels.

The controller 1110 may include at least one of microprocessor, digital signal process, micro controller and logic devices capable of performing functions similar to the functions of those mentioned above. The I/O device 1120 may include a keypad, a keyboard, a display device and so on. The memory device 1130 may store data and/or commands. The interface 1140 may perform a function of transmitting or receiving data to or from communication networks. The interface 1140 may be wired or wireless. For example, the interface 1140 may include an antenna or a wired/wireless transceiver.

The electronic system 1100 may additionally include an operation memory configured to enhance operation of the controller 1110, such as a high-speed dynamic random-access memory (DRAM) and/or a static random access memory (SRAM).

According to the exemplary embodiments of the present disclosure described above, the semiconductor device may be provided within the memory device 1130, or provided as a part of the controller 1110 or the I/O device 1120.

The electronic system 1100 is applicable to a personal digital assistant (PDA) portable computer, a web tablet, a wireless phone, a mobile phone, a digital music player, a memory card, or almost all electronic products that are capable of transmitting and/or receiving data in wireless environment.

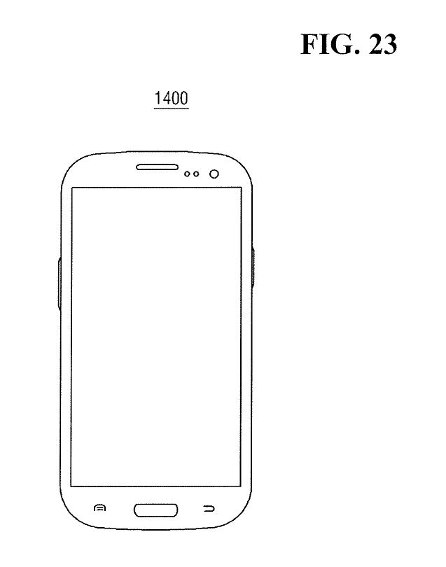

FIGS. 21 to 23 illustrate exemplary semiconductor systems which may apply therein semiconductor devices according to an exemplary embodiment of the present disclosure.

FIG. 21 illustrates a tablet PC 1200, FIG. 22 illustrates a laptop computer 1300, and FIG. 23 illustrates a smartphone 1400. According to an exemplary embodiment of the present disclosure, the semiconductor device may be used in these devices, i.e., in the tablet PC 1200, the laptop computer 1300 or the smartphone 1400. Further, it is apparent to those skilled in the art that the semiconductor device according to an exemplary embodiment of the present disclosure is applicable to another integrated circuit device not illustrated herein. That is, while only the tablet PC 1200, the laptop computer 1300 and the smartphone 1400 are exemplified herein as a semiconductor system according to an exemplary embodiment of the present disclosure, the present disclosure of the semiconductor system is not limited to any of the examples given above.

In an exemplary embodiment of the present disclosure, the semiconductor system may be realized as a computer, an ultra mobile PC (UMPC), a workstation, a net-book, personal digital assistants (PDA), a portable computer, a wireless phone, a mobile phone, an e-book, a portable multimedia player (PMP), a portable game player, a navigation device, a black box, a digital camera, a three-dimensional television, a digital audio recorder, a digital audio player, a digital picture recorder, a digital picture player, a digital video recorder, a digital video player, and so on.

In concluding the detailed description of the embodiments, those skilled in the art will appreciate that many variations and modifications can be made to the preferred embodiments without substantially departing from the principles of the present inventive concept. Therefore, the disclosed preferred embodiments of the present disclosure are used in a generic and descriptive sense only and not for purposes of limitation, and that modifications to the disclosed exemplary embodiments, as well as other exemplary embodiments, are intended to be included within the scope of the appended claims.

What is claimed is:

1. A semiconductor device, comprising:
an internal circuit connected with an input-output terminal; and
an electrostatic discharge (ESD) protection circuit connected to the internal circuit, the ESD protection circuit including a first diode,
wherein the first diode includes:
a first gate which is formed on a substrate and to which a first recovery voltage is applied,
a first well of a first conductivity type which is formed within the substrate and under the first gate,
a first impurity region of the first conductivity type which is formed on one side of the first gate and within the first well, the first impurity region is higher in doping concentration than that of the first well, and
a second impurity region of a second conductivity type which is formed on other side of the first gate and within the first well.

2. The semiconductor device of claim 1, wherein the second impurity region is connected with the input-output terminal, and
the first gate is not electrically connected with the first impurity region and the second impurity region.

3. The semiconductor device of claim 1, wherein the first well is an n-type well, and the first recovery voltage is a positive (+) voltage.

4. The semiconductor device of claim 1, wherein the first well is a p-type well, and the first recovery voltage is a negative (−) voltage.

5. The semiconductor device of claim 1, wherein the ESD protection circuit further includes a second diode, wherein the second diode includes:
a second gate formed on the substrate;
a second well of the second conductivity type, which is formed within the substrate and under the second gate;
a third impurity region of the second conductivity type, which is formed on one side of the second gate and within the second well, the third impurity region is higher in doping concentration than that of the second well; and
a fourth impurity region of the first conductivity type, which is formed on other side of the second gate and within the second well.

6. The semiconductor device of claim 5, wherein a second recovery voltage is applied to the second gate, and
the fourth impurity region is connected with the input-output terminal.

7. The semiconductor device of claim 6, wherein the second gate is not electrically connected with the third impurity region and the fourth impurity region.

8. The semiconductor device of claim 6, wherein the first recovery voltage and the second recovery voltage are different from each other.

9. The semiconductor device of claim 5, further comprising a transistor including a third gate, and a source/drain of the second conductivity type which is formed on both sides of the third gate,
wherein the first recovery voltage is applied to the third gate.

10. The semiconductor device of claim 1, further comprising a buried channel layer formed within the substrate,
wherein an energy bandgap of the buried channel layer is smaller than that of the substrate.

11. A semiconductor device, comprising:
a first well of a first conductivity type and a second well of a second conductivity type, which are formed within a substrate;
a first impurity region of the first conductivity type, which is formed within the first well and connected to a first terminal voltage;
a second impurity region of a second conductivity type, which is formed within the first well;
a third impurity region of the second conductivity type, which is formed within the second well and connected to a second terminal voltage which is different from the first terminal voltage;
a fourth impurity region of the first conductivity type, which is formed within the second well and electrically connected with the second impurity region;
a first gate formed on the substrate between the first impurity region and the second impurity region; and
a second gate formed on the substrate between the third impurity region and the fourth impurity region,
wherein a first recovery voltage applied to the first gate and a second recovery voltage applied to the second gate have different signs from each other.

12. The semiconductor device of claim 11, wherein the first well is an n-type well, and the first recovery voltage is a positive (+) voltage.

13. The semiconductor device of claim 1, wherein the first well is a p-type well, and the first recovery voltage is a negative (−) voltage.

14. The semiconductor device of claim 11, wherein a doping concentration of the first impurity region and a doping concentration of the second impurity region are higher than a doping concentration of the first well, and
a doping concentration of the third impurity region and a doping concentration of the fourth impurity region are higher than a doping concentration of the second well.

15. The semiconductor device of claim 11, wherein the first gate is not electrically connected with the first impurity region and the second impurity region, and
the second gate is not electrically connected with the third impurity region and the fourth impurity region.

16. The semiconductor device of claim 11, further comprising a transistor including a third gate, and a source/drain of the second conductivity type which is formed on both sides of the third gate,
wherein the first recovery voltage is applied to the third gate.

17. The semiconductor device of claim 11, further comprising a buried channel layer formed within the substrate,
wherein an energy bandgap of the buried channel layer is smaller than that of the substrate.

18. The semiconductor device of claim 17, wherein the substrate is a silicon substrate, and the buried channel layer is a silicon germanium layer.

19. A semiconductor device, comprising:
an internal circuit connected with an input-output terminal; and
an electrostatic discharge (ESD) protection circuit connected to the internal circuit, the ESD protection circuit including a first diode and a second diode,
wherein the first diode includes a first gate formed on a substrate and to which a first recovery voltage is applied, a first well of a first conductive type formed under the first gate within the substrate, and a first impurity region of the first conductivity type and a second impurity region of a second conductive type formed within the first well on each side of the first gate,
the second diode includes a second gate formed on the substrate and to which a second recovery voltage is applied, a second well of the second conductive type formed under the second gate within the substrate, and a third impurity region of the second conductivity type and a fourth impurity region of the first conductive type formed within the second well on each side of the second gate, and
the second impurity region and the fourth impurity region are electrically connected to the input-output terminal.

20. The semiconductor device of claim 19, wherein the first well is an n-type well, the second well is a p-type well, the first recovery voltage is a positive (+) voltage, and the second recovery voltage is a negative (−) voltage.
